(19) United States
(12) Patent Application Publication
(10) Pub. No.: US 2017/0183537 A1
(43) Pub. Date: Jun. 29, 2017

(54) POLISHING SLURRY COMPOSITION

(71) Applicants: K.C.TECH CO., LTD, Anseong-si (KR); IUCF-HYU(INDUSTRY-UNIVERSITY COOPERATION FOUNDATION HANYANG UNIVERSITY), Seoul (KR)

(72) Inventors: Joo Hyoung YOON, Anseong-si (KR); Seung Chul HONG, Anseong-si (KR); Young HO YOON, Anseong-si (KR); UnGyu PAIK, Seoul (KR); Ji Hoon SEO, Seoul (KR); Ki Jung KIM, Osan-si (KR); Kang Cheon LEE, Seoul (KR)

(73) Assignees: K.C. TECH CO., LTD, Anseong-si (KR); IUCF-HYU(INDUSTRY-UNIVERSITY COOPERATION FOUNDATION HANYANG UNIVERSITY), Seoul (KR)

(21) Appl. No.: 15/325,095

(22) PCT Filed: Aug. 11, 2015
(86) PCT No.: PCT/KR2015/008370

§ 371 Date: Jan. 10, 2017

(30) Foreign Application Priority Data
Aug. 26, 2014 (KR) 10-2014-0111222
Oct. 30, 2014 (KR) 10-2014-0149265
Jul. 10, 2015 (KR) 10-2015-0098372

(51) Int. Cl. C09G 1/02; H01L 21/28; H01L 21/321; C09K 3/14

(52) U.S. Cl. CPC C09G 1/02; C09K 3/1409; H01L 21/28079; H01L 21/3212

(57) ABSTRACT

The present invention relates to a polishing slurry composition. A polishing slurry composition according to a first aspect of the present invention comprises abrasive particles and an oxidant, polishes tungsten having a thickness of 10-1,000 Å, and improves the topography of tungsten. Additionally, the polishing slurry composition according to a second aspect of the present invention comprises: at least two abrasive particles among first abrasive particles, second abrasive particles and third abrasive particles; and an oxidant, wherein the primary particle size of the first abrasive particles is 20 nm or more and less than 45 nm, the primary particle size of the second abrasive particles is 45 nm or more and less than 130 nm, and the primary particle size of the third abrasive particles is 130 nm or more and less than 250 nm.

### TECHNICAL FIELD

Embodiments relate to a polishing slurry composition.

### BACKGROUND ART

With a decrease in design rules for products, a structure has a narrower width and a greater height, thus drastically increasing an aspect ratio, that is, depth/bottom width ratio, and affecting occurrence of scratches more than two times higher in a 30-nanometer semiconductor process than in a conventional 50-nanometer semiconductor process. Thus, not only scratches but topography also has sensitive effects on the surface of a film material. As crucial factors considered in a polishing process, there are a polishing amount and quality of a polished surface. The decrease in design rules for semiconductors in recent years maximizes importance of quality of a polished surface, and accordingly a polishing process for the quality of the polished surface tends to be added.

Meanwhile, with large-scale integration of semiconductor in recent years, lower current leakage is required, and accordingly a structure of a dielectric with a high dielectric constant and a metal gate is designed to satisfy such a requirement. Generally, aluminum is frequently used as a metal gate material. The decrease in design rules make it difficult to completely deposit and polish aluminum oxides with high hardness, and thus extensive studies on use of tungsten as a gate material are recently conducted. However, as a constituent material of a gate is changed from aluminum to tungsten, tungsten topographies are formed due to particle size of tungsten crystals after deposition, which cause an undesired short circuit between metals to reduce a semiconductor yield. To improve polished surface quality of tungsten, that is, to improve topography, polishing is essential for a next-generation process. A slurry composition which does not improve topography causes over-etching or un-etching of tungsten in a post-polishing process to bring about process defects or to make an operation of a device unstable, thereby drastically reducing a semiconductor yield. In addition, since slurry formation of conventional slurry compositions for polishing tungsten is mostly designed for optimal polishing amount and selectivity with titanium and silicon oxide films, and thus the conventional slurry compositions have low topography improving properties.

### DISCLOSURE OF INVENTION

### Technical Problems

The present invention is to solve the foregoing problems, and an aspect of the present invention is to provide a polishing slurry composition which improves topography of a tungsten film material, thereby reducing metal short circuits and etching defects caused by the topography of the tungsten film material and enabling a next-generation high integration process.

However, the problems to be solved by the present invention are not limited to the foregoing problems, and other problems not mentioned herein would be clearly understood by a person skilled in the art from the following description.

### Technical Solutions

According to a first aspect of the present invention, there is provided a polishing slurry composition including abrasive particles and an oxidizer, polishing tungsten with a thickness of 10 Å to 1000 Å and improving topography of tungsten.

The abrasive particles may include at least one selected from the group consisting of a metal oxide, a metal oxide coated with an organic material or inorganic material and the metal oxide in a colloidal phase, the metal oxide may include at least one selected from the group consisting of silica, ceria, zirconia, alumina, titania, barium titania, germania, mangania and magnesia, and the abrasive particles may be present in an amount of 0.5% by weight (wt %) to 10 wt % in the polishing slurry composition.

The oxidizer may include at least one selected from the group consisting of hydrogen peroxide, iron (II) nitrate, potassium iodate, potassium permanganate, nitric acid, ammonium chlorite, ammonium chlorate, ammonium iodate, ammonium perborate, ammonium perchlorate, ammonium periodate, tetramethylammonium chlorite, tetramethylammonium chlorate, tetramethylammonium iodate, tetramethylammonium perborate, tetramethylammonium perchlorate, tetramethylammonium periodate, 4-methylmorpholine N-oxide, pyridine-N-oxide and urea hydrogen peroxide, and be present in an amount of 0.005 wt % to 5 wt % in the polishing slurry composition.

The polishing slurry composition may be hydrogen peroxide-free or include less than 1 wt % of hydrogen peroxide.

The polishing slurry composition may have a pH ranging from 1 to 4.

According to a second aspect of the present invention, there is provided a polishing slurry composition including at least two of first abrasive particles, second abrasive particles and third abrasive particles; and an oxidizer, wherein the first abrasive particles have a primary particle size of 20 nanometers (nm) to less than 45 nm, the second abrasive particles have a primary particle size of 45 nm to less than 130 nm, and the third abrasive particles have a primary particle size of 130 nm to less than 250 nm.

The first abrasive particles may have a secondary particle size of 30 nm to less than 100 nm, the second abrasive particles have a secondary particle size of 100 nm to less than 250 nm, and the third abrasive particles have a secondary particle size of 250 nm to less than 500 nm.

The first abrasive particles may be present in an amount of 10 wt % to 60 wt % in the entire abrasive particles, the second abrasive particles may be present in an amount of 10 wt % to 60 wt % in the entire abrasive particles, and the third abrasive particles may be present in an amount of 10 wt % to 60 wt % in the entire abrasive particles.

The first abrasive particles, the second abrasive particles and the third abrasive particles may independently include at least one selected from the group consisting of a metal oxide, a metal oxide coated with an organic material or inorganic material and the metal oxide in a colloidal phase, and the metal oxide may include at least one selected from the group consisting of silica, ceria, zirconia, alumina, titania, barium titania, germania, mangania and magnesia.

The oxidizer may include at least one selected from the group consisting of hydrogen peroxide, iron (II) nitrate, potassium iodate, potassium permanganate, nitric acid, ammonium chlorite, ammonium chlorate, ammonium iodate, ammonium perborate, ammonium perchlorate, ammonium periodate, tetramethylammonium chlorite, tetramethylammonium chlorate, tetramethylammonium iodate, tetramethylammonium perborate, tetramethylammonium perchlorate, tetramethylammonium periodate, 4-methylmorpholine N-oxide, pyridine-N-oxide and urea hydrogen peroxide, and be present in an amount of 0.005 wt % to 5 wt % in the polishing slurry composition.

The polishing slurry composition may be hydrogen peroxide-free or include less than 1 wt % of hydrogen peroxide.

The polishing slurry composition may further include at least one pH adjuster selected from the group consisting of an inorganic acid or inorganic acid salt containing at least one selected from the group consisting of hydrochloric acid, nitric acid, phosphoric acid, sulfuric acid, hydrofluoric acid, bromic acid, iodic acid and salts thereof; and an organic acid or organic acid salt containing at least one selected from the group consisting of formic acid, malonic acid, maleic acid, oxalic acid, acetic acid, adipic acid, citric acid, propionic acid, fumaric acid, lactic acid, salicylic acid, pimelic acid, benzoic acid, succinic acid, phthalic acid, butyric acid, glutaric acid, glutamic acid, glycolic acid, asparaginic acid, tartaric acid and salts thereof.

A surface of a tungsten-containing film may have a peak to valley (Rpv) of 100 nm or less and roughness (Rq) of 10 nm or less after polishing using the polishing slurry composition.

The abrasive particles may have a contact area of 0.5 to 0.9, and the contact area may be calculated by Equation 1:

A=C₀^{1/3}·φ^{-1/3} [Equation 1]

where A is the contact area, C₀ is concentration wt % of the abrasive particles, and φ is diameter (nm) of the particles.

### Effects of the Invention

A polishing slurry composition according to the present invention improves a yield affected by metal short circuits and etching defects caused by topography of a film material in polishing tungsten and enables a next-generation high integration process. Further, the polishing slurry composition removes only topographies of tungsten, thereby avoiding waste of tungsten due to excessive polishing and reducing surface defects caused by erosion, dishing and formation of residues of a metal layer on a surface of a polishing target.

A polishing slurry composition according to the present invention is prepared by mixing two or three kinds of abrasive particles, improves a yield affected by metal short circuits and etching defects caused by topography of a film material in polishing tungsten, and enables a next-generation high integration process. Further, the polishing slurry composition removes only topographies of tungsten, thereby avoiding waste of tungsten due to excessive polishing and reducing surface defects caused by erosion, dishing and formation of residues of a metal layer on a surface of a polishing target.

### BRIEF DESCRIPTION OF DRAWINGS

FIG. 1 is a topographic image of a tungsten film material.

FIG. 2 is a cross-sectional view illustrating improvement in topography of a tungsten film material using a polishing slurry composition according to an example of a first aspect of the present invention.

FIG. 3 illustrates a topographic image of a surface of tungsten before polishing.

FIG. 4 illustrates a topographic image of a surface of tungsten after polishing using a polishing slurry composition according to a comparative example.

FIG. 5 illustrates a topographic image of a surface of tungsten after polishing using the polishing slurry composition according to the example of the first aspect of the present invention.

FIG. 6 illustrates polishing rates of tungsten wafers using polishing slurry compositions according to Comparative Examples 1 to 3 and Examples 1 to 7 of a second aspect of the present invention.

FIGS. 7 to 16 illustrate topographic images of a surface of tungsten after polishing using the polishing slurry compositions according to Comparative Examples 1 to 3 and Examples 1 to 7 of the second aspect of the present invention.

### DETAILED DESCRIPTION FOR CARRYING OUT THE INVENTION

Hereinafter, embodiments of the present invention will be described in detail with reference to the accompanying drawings. When it is determined detailed description related to a related known function or configuration they may make the purpose of the present invention unnecessarily ambiguous in describing the present invention, the detailed description will be omitted here. Also, terms used herein are defined to appropriately describe the embodiments of the present invention and thus may be changed depending on a user, the intent of an operator, or a custom. Accordingly, the terms must be defined based on the following overall description of this specification. Like reference numerals present in the drawings refer to the like elements throughout.

It will be understood throughout the whole specification that, unless specified otherwise, when one part “includes” one component, the part does not exclude other components but may further include the other components.

Hereinafter, a polishing slurry composition of the present invention will be described in detail with reference to embodiments and drawings. However, the present invention is not limited to these embodiments and drawings.

According to a first aspect of the present invention, there may be provided a polishing slurry composition which includes abrasive particles; and an oxidizer, polishes tungsten with a thickness of 10 Å to 1000 Å, and improves topography of tungsten.

The polishing slurry composition according to the first aspect of the present invention is a polishing slurry composition which may be used to improve topography of tungsten rather than to secure a polishing amount of tungsten, particularly to improve topography for formation of a tungsten gate.

The polishing slurry composition according to the first aspect of the present invention may be for polishing tungsten with a thickness of, for example, 10 Å to 1000 Å, preferably 50 Å to 500 Å.

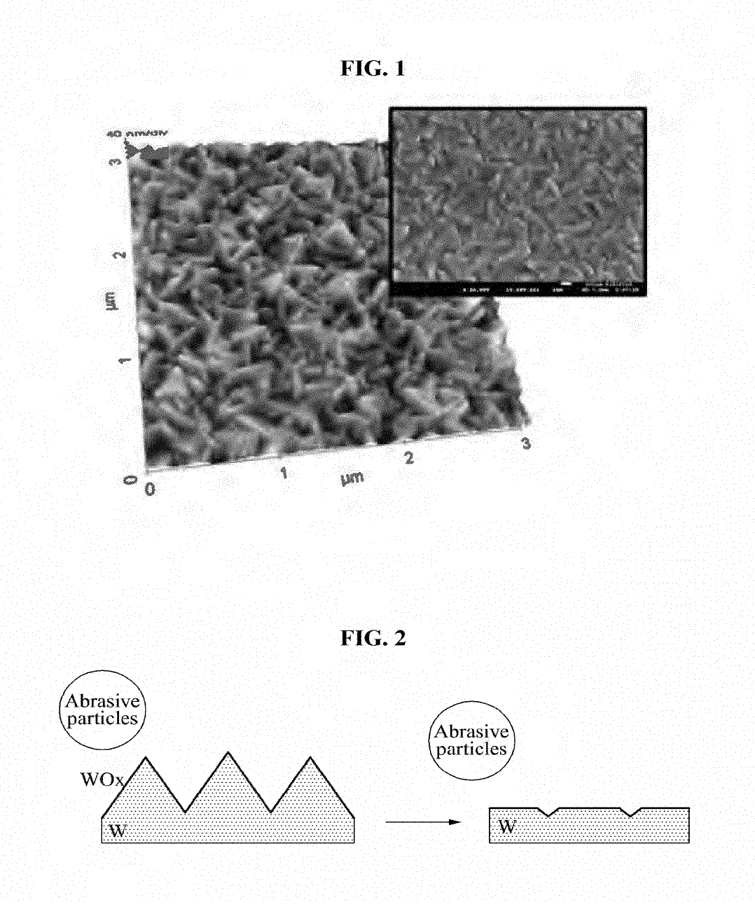

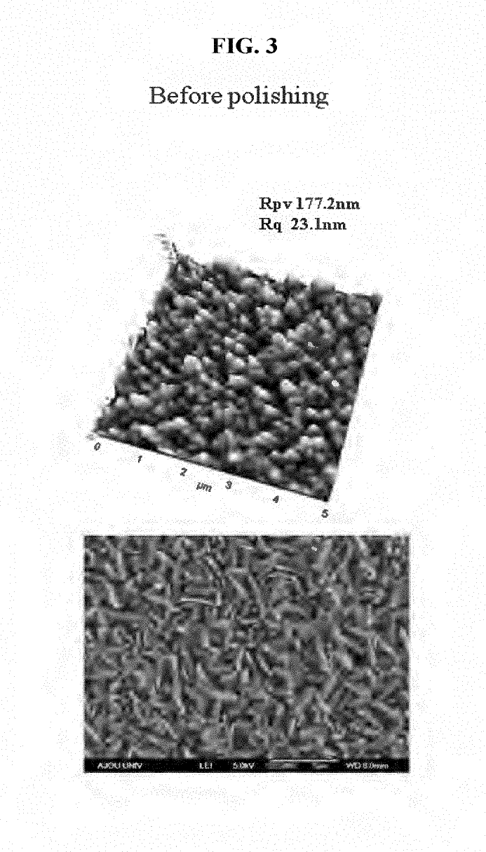

FIG. 1 is a topographic image of a tungsten film material, and FIG. 2 is a cross-sectional view illustrating improvement in topography of a tungsten film material using a polishing slurry composition according to an example of the first aspect of the present invention. Viewed from a side, the topography of the tungsten film material has uneven conical shapes. Unlike a conventional slurry composition for improving topography of tungsten, the polishing slurry composition according to the present invention removes only topographies of tungsten and avoids waste of tungsten due to excessive polishing.

A surface of tungsten polished using the polishing slurry composition according to the first aspect of the present invention may have a peak to valley (Rpv) of 100 nanometers (nm) or less, as necessary 10 nm or less, and a roughness (Rq) of 10 nm or less, as necessary 1.5 nm or less. The peak to valley value and roughness may be measured with a scanning probe microscope.

The abrasive particles may include at least one selected from the group consisting of a metal oxide, a metal oxide coated with an organic material or inorganic material and the metal oxide in a colloidal phase, and the metal oxide may include at least one selected from the group consisting of silica, ceria, zirconia, alumina, titania, barium titania, germania, mangania and magnesia.

The abrasive particles may have a size of 10 nm to 300 nm, as necessary 50 nm to 100 nm. Since the abrasive particles are synthesized in a liquid phase, the abrasive particles need to have a size of 300 nm or less in order to secure particle uniformity. When the size of the abrasive particles is less than 10 nm, too many small particles are present to reduce washing performance and defects occur excessively on a wafer surface to reduce polishing rate. When the size of the abrasive particles is greater than 300 nm, monodispersibility may not be achieved to cause occurrence of surface defects, such as scratches.

The abrasive particles may have a bimodal particle distribution in which large abrasive particles with a size of 50 nm 300 nm, as necessary 50 nm to 100 nm, and small abrasive particles with a size of 10 nm to 50 nm, as necessary 20 nm to 50 nm, are mixed by adjusting calcination conditions and/or milling conditions. As relatively large abrasive particles and relatively small particles are mixed, the polishing slurry composition has superior dispersibility, thereby expecting an effect of reducing scratches on a wafer surface.

The abrasive particles may be present in an amount of 0.5% by weight (wt %) to 10 wt % in the polishing slurry composition. When the amount of the abrasive particles is less than 0.5 wt % in the polishing slurry composition, the polishing slurry composition may not sufficiently polish a film to be polished, for example, tungsten, in polishing to reduce planarization rate. When the amount of the abrasive particles is greater than 10 wt %, the abrasive particles may cause defects and scratches.

The oxidizer may include at least one selected from the group consisting of hydrogen peroxide, iron (II) nitrate, potassium iodate, potassium permanganate, nitric acid, ammonium chlorite, ammonium chlorate, ammonium iodate, ammonium perborate, ammonium perchlorate, ammonium periodate, tetramethylammonium chlorite, tetramethylammonium chlorate, tetramethylammonium iodate, tetramethylammonium perborate, tetramethylammonium perchlorate, tetramethylammonium periodate, 4-methylmorpholine N-oxide, pyridine-N-oxide and urea hydrogen peroxide. Among these, hydrogen peroxide is preferably used in view of oxidizing power, dispersion stability of the slurry and affordability.

The oxidizer may be present in an amount of 0.005 wt % to 5 wt %, preferably 0.05 wt % to 1 wt % in the polishing slurry composition. When the amount of the oxidizer is less than 0.005 wt % in the polishing slurry composition, polishing rate and etching speed of tungsten may be reduced. When the amount of the oxidizer is greater than 5 wt %, an oxide film on the tungsten surface becomes hard so that polishing is not properly performed and the oxide film grows to cause dishing and erosion of tungsten, thus resulting in inferior topography properties. Thus, since the oxidizer directly affects the polishing speed and etching speed of tungsten, the polishing slurry composition of the present invention, which is for improving surface quality of tungsten, needs to use a reduced concentration of hydrogen peroxide. Thus, the polishing slurry composition according to the present invention may be hydrogen peroxide-free or include less than 1 wt % of hydrogen peroxide.

As necessary, the polishing slurry composition according to the first aspect of the present invention may also include a pro-oxidant. The pro-oxidant may include at least one selected from the group consisting of an iron compound, a ferrocyanide, a chlorate, a dichromate, a hypochlorate, a nitrate, a persulfate and a permanganate. Among the pro-oxidants, an iron compound, which is a compound dissociated in water to provide an iron ion (Fe²⁺ or Fe³⁺), specifically a ferric nitride may be used.

The pro-oxidant may be present in an amount of 0.05 wt % to 10 wt % in the polishing slurry composition. When the amount of the pro-oxidant is less than 0.05 wt %, it is difficult to obtain polishing speed sufficient for removing topographies. When the amount of the pro-oxidant is greater than 10 wt %, tungsten may be excessively oxidized in polishing or dispersion properties of the slurry may be reduced.

A pH adjuster may be further added as a material used to prevent corrosion of a metal or abrader and to realize a pH range in which oxidation of a metal easily occurs and be, for example, at least one selected from the group consisting of hydrochloric acid, nitric acid, sulfuric acid, acetic acid, phosphoric acid, boric acid, amino acid, sodium hydroxide, potassium hydroxide, ammonia, an ammonia derivative, citric acid, tartaric acid, formic acid, maleic acid and oxalic acid.

pH of the polishing slurry composition according to the present invention may preferably be adjusted to achieve dispersion stability and appropriate polishing speed depending on the abrasive particles and be in an acid range from 1 to 4, preferably 2 to 3.

The polishing slurry composition may be for polishing a tungsten-containing substrate. The tungsten-containing substrate may include tungsten, tantalum, ruthenium, hafnium, other refractory metals, nitrides and silicides thereof.

According to a second aspect of the present invention, there may be provided a polishing slurry composition including at least two of first abrasive particles, second abrasive particles and third abrasive particles; and an oxidizer, in which the first abrasive particles have a primary particle size of 20 nm to less than 45 nm, the second abrasive particles have a primary particle size of 45 nm to less than 130 nm, and the third abrasive particles have a primary particle size of 130 nm to less than 250 nm.

The polishing slurry composition according to the second aspect of the present invention is a polishing slurry composition which may be used to improve topography of tungsten rather than to secure a polishing amount of tungsten, particularly to improve topography for formation of a tungsten gate. The polishing slurry composition includes two or three kinds of abrasive particles to considerably reduce surface defects by erosion, dishing and formation of residues of a metal layer on a surface of a polishing target.

Viewed from a side, the topography of a tungsten film material has uneven conical shapes. Unlike a conventional slurry composition for improving topography of tungsten, the polishing slurry composition according to the present invention removes only topographies of tungsten and avoids waste of tungsten due to excessive polishing.

The first abrasive particles may have a secondary particle size of 30 nm to less than 100 nm, the second abrasive particles may have a secondary particle size of 100 nm to less than 250 nm, and the third abrasive particles may have a secondary particle size of 250 nm to less than 500 nm.

The first abrasive particles, the second abrasive particles and the third abrasive particles may be prepared by adjusting calcination conditions and/or milling conditions, and the first abrasive particles and the second abrasive particles, the first abrasive particles and the third abrasive particles, or the second abrasive particles and the third abrasive particles may be mixed in a bimodal particle distribution. Alternatively, the first abrasive particles, the second abrasive particles and the third abrasive particles are mixture all together in a particle distribution having three peaks. As relatively large abrasive particles and relatively small particles are mixed, the polishing slurry composition has superior dispersibility, thereby expecting an effect of reducing scratches on a wafer surface.

The first abrasive particles, the second abrasive particles and the third abrasive particles may independently include at least one selected from the group consisting of a metal oxide, a metal oxide coated with an organic material or inorganic material and the metal oxide in a colloidal phase, and the metal oxide may include at least one selected from the group consisting of silica, ceria, zirconia, alumina, titania, barium titania, germania, mangania and magnesia.

The first abrasive particles may be present in an amount of 10 wt % to 60 wt % in the entire abrasive particles, the second abrasive particles may be present in an amount of 10 wt % to 60 wt % in the entire abrasive particles, and the third abrasive particles may be present in an amount of 10 wt % to 60 wt % in the entire abrasive particles.

Improvement in topography of a tungsten film is related to contact area between an abrasive and the tungsten film. When the first abrasive particles, the second abrasive particles and the third abrasive particles are mixed within the foregoing ranges to be used an abrasive, topography improvement effect is excellent. Particularly, the ranges may be determined for improving dispersion stability by calculating the contact area between the abrasive and the tungsten film according to a mixing ratio.

The abrasive particles may be present in an amount of 0.5 wt % to 10 wt % in the polishing slurry composition. The abrasive particles may be present in the polishing slurry composition within the foregoing range based on the total amount of abrasive particles regardless of the first abrasive particles, the second abrasive particles and the third abrasive particles. When the amount of the abrasive particles is less than 0.5 wt % in the polishing slurry composition, the polishing slurry composition may not sufficiently polish a film to be polished, for example, tungsten, in polishing to reduce planarization rate. When the amount of the abrasive particles is greater than 10 wt %, the abrasive particles may cause defects and scratches.

The abrasive particles may have a contact area of 0.5 to 0.9. When the contact area of the abrasive particles is out of the range, a small contact area between the abrasive particles and the tungsten film material may not achieve sufficient polishing and not improve topography of the tungsten film material.

The contact area may be calculated by the following Equation 1:

A=C₀^{1/3}·φ^{-1/3} [Equation 1]

In Equation 1, A is the contact area, C₀ is concentration wt % of the abrasive particles, and φ is diameter (nm) of the particles.

The oxidizer may include at least one selected from the group consisting of hydrogen peroxide, iron (II) nitrate, potassium iodate, potassium permanganate, ammonium chlorite, ammonium chlorate, ammonium iodate, ammonium perborate, ammonium perchlorate, ammonium periodate, tetramethylammonium chlorite, tetramethylammonium chlorate, tetramethylammonium iodate, tetramethylammonium perborate, tetramethylammonium perchlorate, tetramethylammonium periodate, 4-methylmorpholine N-oxide, pyridine-N-oxide and urea hydrogen peroxide. Among these, hydrogen peroxide is preferably used in view of oxidizing power, dispersion stability of the slurry and affordability.

The oxidizer may be present in an amount of 0.005 wt % to 5 wt %, preferably 0.05 wt % to 1 wt % in the polishing slurry composition. When the amount of the oxidizer is less than 0.005 wt % in the polishing slurry composition, polishing rate and etching speed of tungsten may be reduced. When the amount of the oxidizer is greater than 5 wt %, an oxide film on the tungsten surface becomes hard so that polishing is not properly performed and the oxide film grows to cause dishing and erosion of tungsten, thus resulting in inferior topography properties.

Thus, since the oxidizer directly affects the polishing speed and etching speed of tungsten, the polishing slurry composition of the present invention, which is for improving surface quality of tungsten, needs to use a reduced concentration of hydrogen peroxide. Thus, the polishing slurry composition according to the present invention may be hydrogen peroxide-free or include less than 1 wt % of hydrogen peroxide.

A pH adjuster may be further added as a material used to prevent corrosion of a metal or abrader and to realize a pH range in which oxidation of a metal easily occurs. For example, the pH adjuster may include at least one selected from the group consisting of an inorganic acid or inorganic acid salt containing at least one selected from the group consisting of hydrochloric acid, nitric acid, phosphoric acid, sulfuric acid, hydrofluoric acid, bromic acid, iodic acid and salts thereof; and an organic acid or organic acid salt containing at least one selected from the group consisting of formic acid, malonic acid, maleic acid, oxalic acid, acetic acid, adipic acid, citric acid, propionic acid, fumaric acid, lactic acid, salicylic acid, pimelic acid, benzoic acid, succinic acid, phthalic acid, butyric acid, glutaric acid, glutamic acid, glycolic acid, asparaginic acid, tartaric acid and salts thereof.

pH of the polishing slurry composition according to the second aspect of the present invention may preferably be adjusted to achieve dispersion stability and appropriate polishing speed depending on the abrasive particles and be in an acid range from 1 to 4, preferably 2 to 3.

The polishing slurry composition may be for polishing a tungsten-containing substrate. The tungsten-containing substrate may include tungsten, tantalum, ruthenium, hafnium, other refractory metals, nitrides and silicides thereof.

The polishing slurry composition may be for polishing tungsten with a thickness of 10 Å/min to 1000 Å/min.

A surface of a tungsten-containing film polished using the polishing slurry composition according to the second aspect of the present invention may have a peak to valley (Rpv) of 100 nm or less and a roughness (Rq) of 10 nm or less. The peak to valley value and roughness may be measured with a scanning probe microscope.

The polishing slurry composition according to the second aspect of the present invention is prepared by mixing two or three kinds of abrasive particles, improves a yield affected by metal short circuits and etching defects caused by topography of a film material in polishing tungsten, and enables a next-generation high integration process. Further, the polishing slurry composition removes only topographies of tungsten, thereby avoiding waste of tungsten due to excessive polishing and reducing surface defects caused by erosion, dishing and formation of residues of a metal layer on a surface of a polishing target.

Hereinafter, the first aspect of the present invention will be described in detail with reference to an example and a comparative example as follows. However, the technical idea of the present invention is not limited or restricted to the examples.

### EXAMPLE

A polishing slurry composition with a pH of 2.5 for improving topography of tungsten was prepared by mixing 3.5 wt % of silica and 0.5 wt % of hydrogen peroxide and adjusting pH with nitric acid.

### COMPARATIVE EXAMPLE

A polishing slurry composition was prepared by mixing 3.5 wt % of silica and 8 wt % of hydrogen peroxide.

Tungsten-containing wafers were polished using the polishing slurry compositions according to the example and the comparative example under the following polishing conditions.

[Polishing conditions]

1. Polishing equipment: CETR CP-4 manufactured by Bruker Corporation

2. Wafer: 6 cm×6 cm tungsten wafer

3. Platen pressure: 3 psi

4. Spindle speed: 69 rpm

5. Platen speed: 70 rpm

6. Flow rate: 100 ml/min

7. Slurry solid content: 3.5 wt %

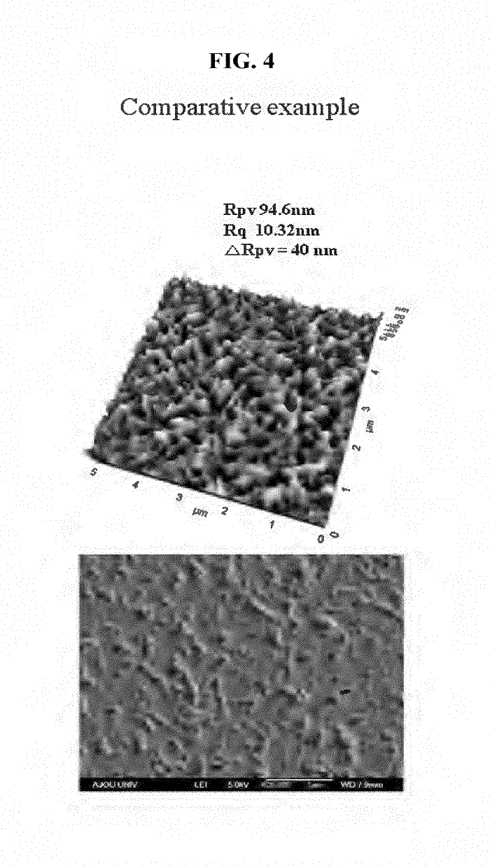

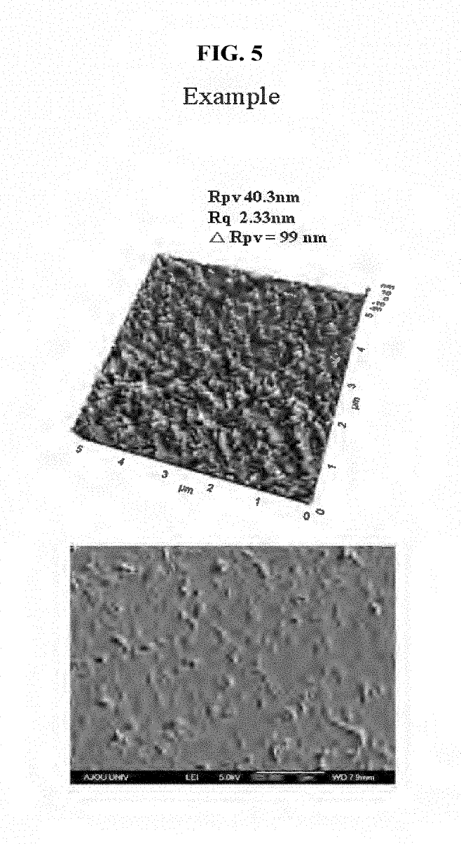

FIG. 3 illustrates a topographic image of a surface of tungsten before polishing, FIG. 4 illustrates a topographic image of a surface of tungsten after polishing using the polishing slurry composition according to the comparative example, and FIG. 5 illustrates a topographic image of a surface of tungsten after polishing using the polishing slurry composition according to the example of the first aspect of the present invention. When the polishing slurry composition of the comparative example was used, polishing was performed at 330 Å/min. When the polishing slurry composition of the example was used, polishing was performed at 556 Å/min. It is seen that the polishing slurry composition according to the example of the present invention removed only topographies of tungsten merely by adding a trace of hydrogen peroxide.

Hereinafter, the second aspect of the present invention will be described in detail with reference to examples and comparative examples as follows. However, the technical idea of the present invention is not limited or restricted to the examples.

### Comparative Example 1

A polishing slurry composition was prepared by mixing 3.5 wt % of first silica abrasive particles in the entire polishing slurry composition and 0.5 wt % of hydrogen peroxide. pH of the polishing slurry composition was adjusted to 2.5 with nitric acid.

### Comparative Example 2

A polishing slurry composition was prepared in the same manner as in Comparative Example 1 except that second silica abrasive particles were used.

### Comparative Example 3

A polishing slurry composition was prepared in the same manner as in Comparative Example 1 except that third silica abrasive particles were used.

### Example 1

A polishing slurry composition was prepared in the same manner as in Comparative Example 1 except that a mixture of two kinds of abrasive particles, 50% of the first silica abrasive particles and 50% of the second silica abrasive particles, was used.

### Example 2

A polishing slurry composition was prepared in the same manner as in Comparative Example 1 except that a mixture of two kinds of abrasive particles, 50% of the first silica abrasive particles and 50% of the third silica abrasive particles, was used.

### Example 3

A polishing slurry composition was prepared in the same manner as in Comparative Example 1 except that a mixture of two kinds of abrasive particles, 50% of the second silica abrasive particles and 50% of the third silica abrasive particles, was used.

### Example 4

A polishing slurry composition was prepared in the same manner as in Comparative Example 1 except that a mixture of three kinds of abrasive particles, 20% of the first silica abrasive particles, 40% of the second silica abrasive particles and 40% of the third silica abrasive particles, was used.

### Example 5

A polishing slurry composition was prepared in the same manner as in Comparative Example 1 except that a mixture of three kinds of abrasive particles, 40% of the first silica abrasive particles, 20% of the second silica abrasive particles and 40% of the third silica abrasive particles, was used.

### Example 6

A polishing slurry composition was prepared in the same manner as in Comparative Example 1 except that a mixture of three kinds of abrasive particles, 40% of the first silica abrasive particles, 40% of the second silica abrasive particles and 20% of the third silica abrasive particles, was used.

### Example 7

A polishing slurry composition was prepared in the same manner as in Comparative Example 1 except that a mixture of three kinds of abrasive particles, 33.3% of the first silica abrasive particles, 33.3% of the second silica abrasive particles and 33.3% of the third silica abrasive particles, was used.

Tungsten wafers were polished using the polishing slurry compositions according to Comparative Examples 1 to 3 and Examples 1 to 7 of the second aspect of the present invention under the following polishing conditions.

[Polishing Conditions]

1. Polishing equipment: CETR CP-4

2. Wafer: 6 cm×6 cm tungsten wafer

3. Platen pressure: 4 psi

4. Spindle speed: 69 rpm

5. Platen speed: 70 rpm

6. Flow rate: 100 ml/min

7. Slurry solid content: 3.5 wt %

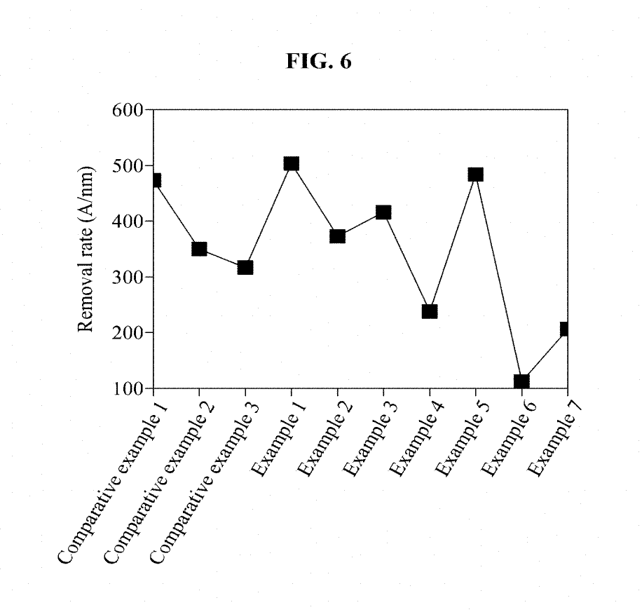

FIG. 6 illustrates polishing rates of the tungsten wafers using the polishing slurry compositions according to Comparative Examples 1 to 3 and Examples 1 to 7 of the second aspect of the present invention. When the polishing slurry composition of Example 6 in which three kinds of abrasive particles, 40% of the first silica abrasive particles, 40% of the second silica abrasive particles and 20% of the third silica abrasive particles, were mixed was used, a lowest polishing rate was obtained.

Table 1 illustrates contact areas on the tungsten topography surface after polishing using the polishing slurry compositions according to Comparative Examples 1 to 3 and Examples 1 to 7 of the second aspect of the present invention.

TABLE 1

| | | | Contact |
|---|---|---|---|
| | Particles | Rate (%) | area |
| Comparative | First abrasive particles | 100 | 0.498 |
| Example 1 | | | |
| Comparative | Second abrasive particles | 100 | 0.375 |
| Example 2 | | | |
| Comparative | Third abrasive particles | 100 | 0.264 |
| Example 3 | | | |
| Example 1 | First abrasive particles | 50 | 0.395 |
| | Second abrasive particles | 50 | 0.298 |
| | Total | 100 | 0.693 |
| Example 2 | First abrasive particles | 50 | 0.395 |
| | Third abrasive particles | 50 | 0.210 |
| | Total | 100 | 0.605 |
| Example 3 | Second abrasive particles | 50 | 0.298 |
| | Third abrasive particles | 50 | 0.210 |
| | Total | 100 | 0.508 |
| Example 4 | First abrasive particles | 20 | 0.291 |
| | Second abrasive particles | 40 | 0.277 |
| | Third abrasive particles | 40 | 0.195 |
| | Total | 100 | 0.763 |
| Example 5 | First abrasive particles | 40 | 0.367 |
| | Second abrasive particles | 20 | 0.219 |
| | Third abrasive particles | 40 | 0.194 |
| | Total | 100 | 0.780 |
| Example 6 | First abrasive particles | 40 | 0.367 |
| | Second abrasive particles | 40 | 0.277 |
| | Third abrasive particles | 20 | 0.155 |
| | Total | 100 | 0.799 |
| Example 7 | First abrasive particles | 33.33 | 0.344 |
| | Second abrasive particles | 33.33 | 0.259 |
| | Third abrasive particles | 33.33 | 0.183 |
| | Total | 100 | 0.786 |

Regarding total contact areas of the polishing slurry compositions according to Comparative Examples 1 to 3 and Examples 1 to 7, Examples 4 to 7 in which three kinds of silica particles were mixed have greatest total contact areas, and Examples 1 to 3 in which two kinds of silica particles were mixed have greater total contact areas than Comparative Examples 1 to 3 in which a single kind of silica particles was used. Thus, Examples 4 to 7 having the greatest total contact areas in which three kinds of silica particles were mixed are favorable for improvement in tungsten topography.

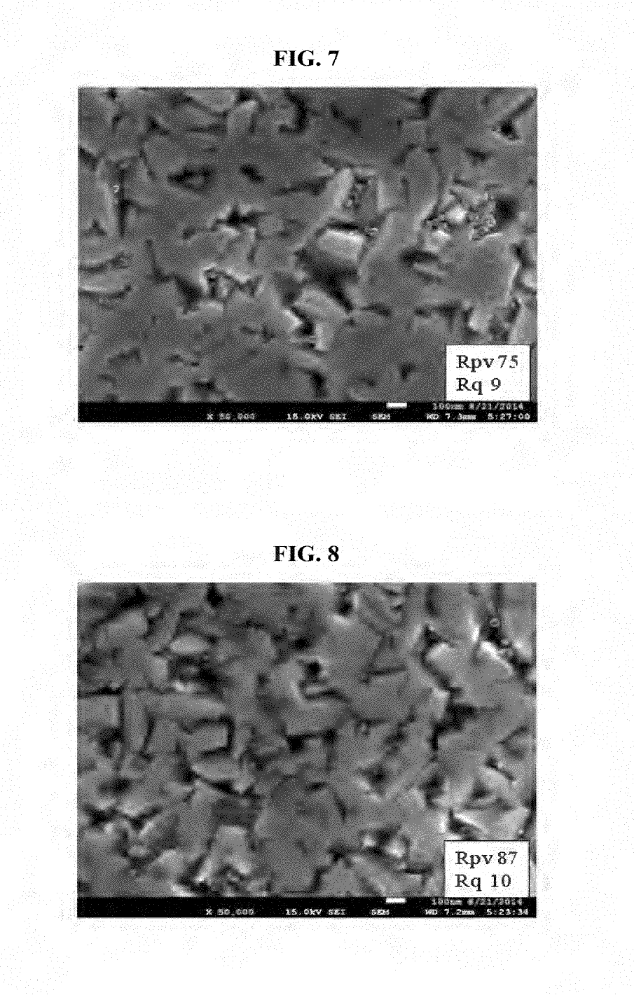

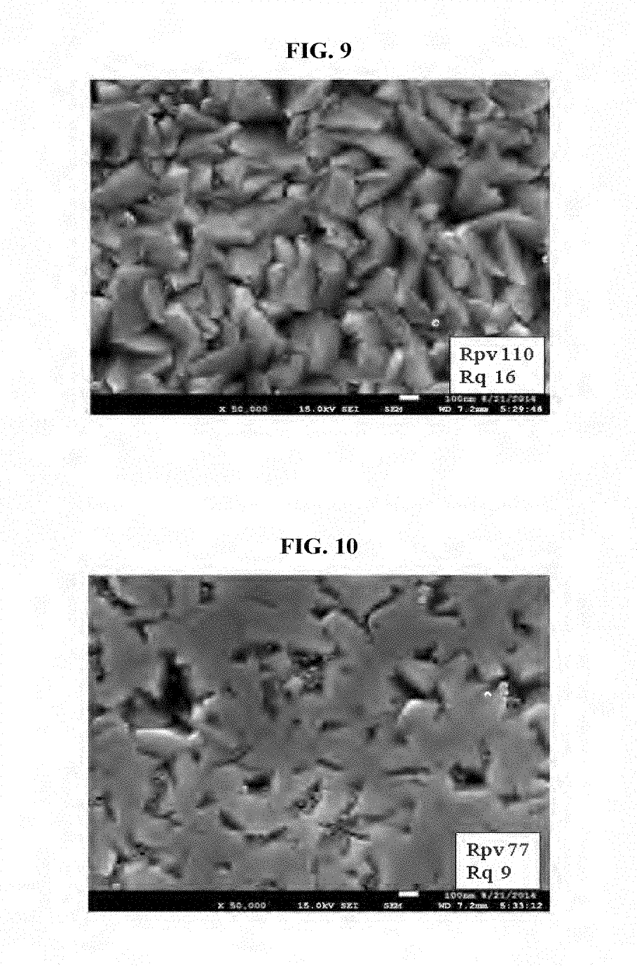

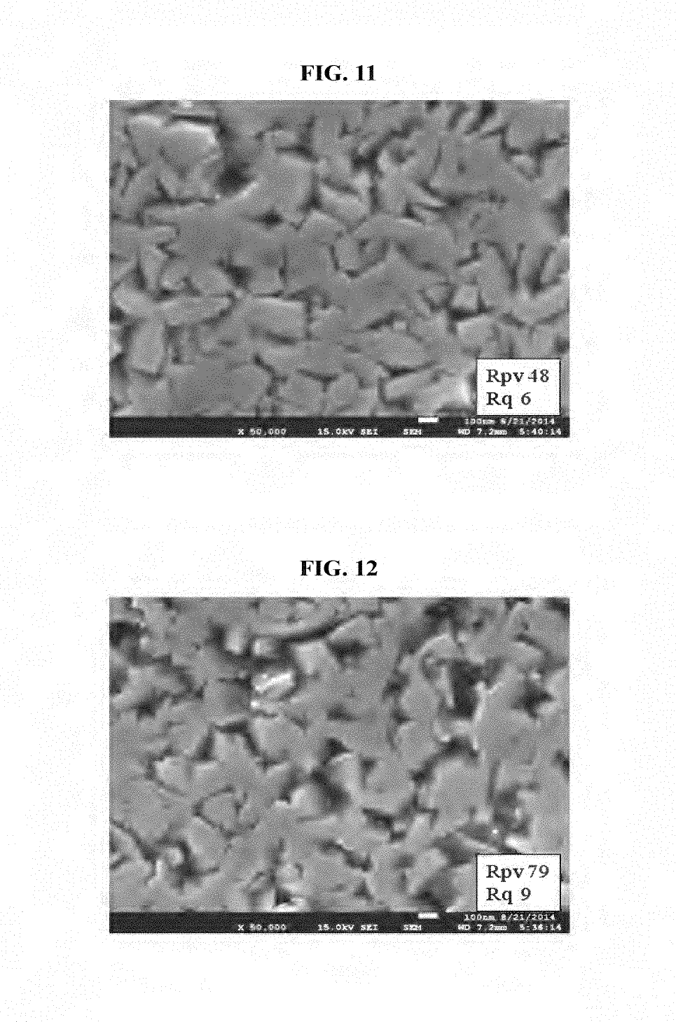

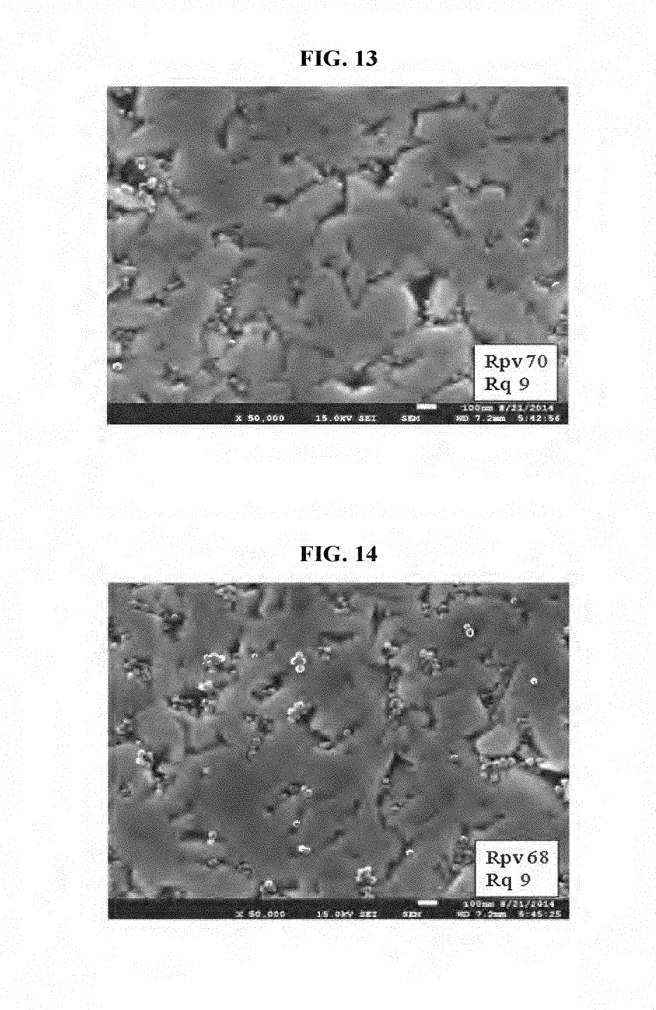

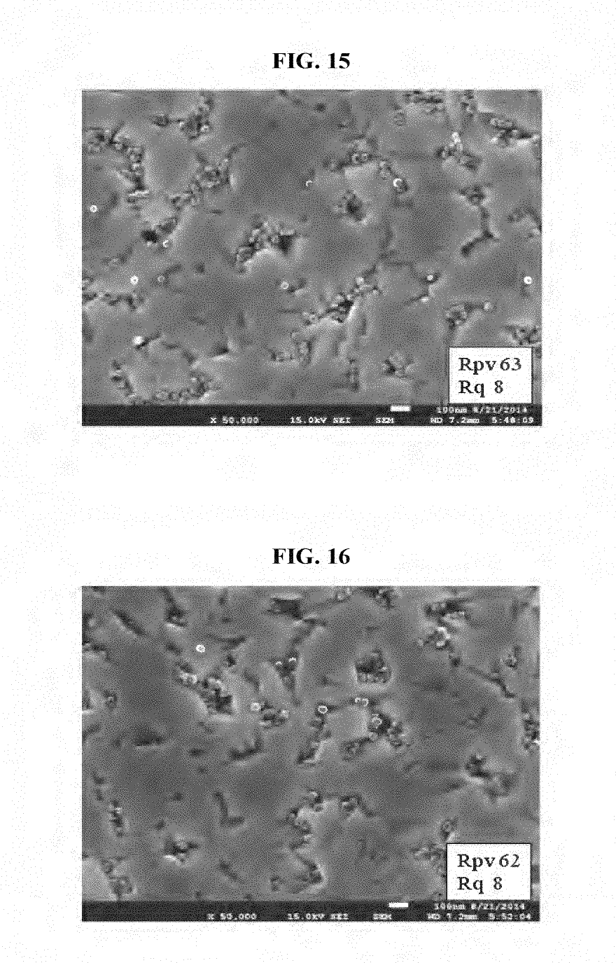

FIGS. 7 to 16 illustrate topographic images of a surface of tungsten after polishing using the polishing slurry compositions according to Comparative Examples 1 to 3 and Examples 1 to 7 of the second aspect of the present invention. Referring to FIGS. 7 to 16, Examples 1 to 7 are superior for improving surface topography to Comparative Examples 1 to 3. In particular, the surfaces according to Examples 1 to 3 are superior to the surfaces according to Examples 4 to 7, which shows that the polishing slurry compositions in which three kinds of silica were mixed increase total contact area in polishing tungsten topographies more than the polishing slurry compositions in which two kinds of silica were mixed.

Accordingly, it is verified that the polishing slurry compositions including mixtures of two or three kinds of silica particles improve tungsten topography as compared with the polishing slurry compositions including a single kind of silica particles. In particular, the polishing slurry compositions including the mixtures of three kinds of silica particles are superior for improving tungsten topography to the polishing slurry compositions including the mixtures of two kinds of silica particles. That is, it is verified that that an increase in total contact area leads to superior topography improvement.

Although the present invention has been shown and described with reference to a few embodiments and the accompanying drawings, the present invention is not limited to the described embodiments. Instead, it will be apparent to those skilled in the art that various modifications and variations may be made from the foregoing descriptions. Therefore, the scope of the present invention is not limited by the aforementioned embodiments but is defined by the appended claims and their equivalents.

1. A polishing slurry composition comprising:
abrasive particles; and
an oxidizer,
wherein the polishing slurry composition polishes tungsten having a thickness of 10 Å to 1000 Å and improves topography of tungsten.

2. The polishing slurry composition of claim 1, wherein the abrasive particles comprise at least one selected from the group consisting of a metal oxide, a metal oxide coated with an organic material or inorganic material and the metal oxide in a colloidal phase,
the metal oxide comprises at least one selected from the group consisting of silica, ceria, zirconia, alumina, titania, barium titania, germania, mangania and magnesia, and
the abrasive particles are present in an amount of 0.5% by weight (wt %) to 10 wt % in the polishing slurry composition.

3. The polishing slurry composition of claim 1, wherein the oxidizer comprises at least one selected from the group consisting of hydrogen peroxide, iron (II) nitrate, potassium iodate, potassium permanganate, nitric acid, ammonium chlorite, ammonium chlorate, ammonium iodate, ammonium perborate, ammonium perchlorate, ammonium periodate, tetramethylammonium chlorite, tetramethylammonium chlorate, tetramethylammonium iodate, tetramethylammonium perborate, tetramethylammonium perchlorate, tetramethylammonium periodate, 4-methylmorpholine N-oxide, pyridine-N-oxide and urea hydrogen peroxide, and is present in an amount of 0.005 wt % to 5 wt % in the polishing slurry composition.

4. The polishing slurry composition of claim 1, wherein the polishing slurry composition is hydrogen peroxide-free or comprises less than 1 wt % of hydrogen peroxide.

5. The polishing slurry composition of claim 1, wherein the polishing slurry composition has a pH ranging from 1 to 4.

6. A polishing slurry composition comprising:
at least two of first abrasive particles, second abrasive particles and third abrasive particles; and
an oxidizer,
wherein the first abrasive particles have a primary particle size of 20 nanometers (nm) to less than 45 nm,
the second abrasive particles have a primary particle size of 45 nm to less than 130 nm, and
the third abrasive particles have a primary particle size of 130 nm to less than 250 nm.

7. The polishing slurry composition of claim 6, wherein
the first abrasive particles have a secondary particle size of 30 nm to less than 100 nm,
the second abrasive particles have a secondary particle size of 100 nm to less than 250 nm, and
the third abrasive particles have a secondary particle size of 250 nm to less than 500 nm.

8. The polishing slurry composition of claim 6, wherein
the first abrasive particles are present in an amount of 10 wt % to 60 wt % in the entire abrasive particles,
the second abrasive particles are present in an amount of 10 wt % to 60 wt % in the entire abrasive particles, and
the third abrasive particles are present in an amount of 10 wt % to 60 wt % in the entire abrasive particles.

9. The polishing slurry composition of claim 6, wherein the first abrasive particles, the second abrasive particles and the third abrasive particles independently comprise at least one selected from the group consisting of a metal oxide, a metal oxide coated with an organic material or inorganic material and the metal oxide in a colloidal phase, and
the metal oxide comprises at least one selected from the group consisting of silica, ceria, zirconia, alumina, titania, barium titania, germania, mangania and magnesia.

10. The polishing slurry composition of claim 6, wherein the oxidizer comprises at least one selected from the group consisting of hydrogen peroxide, iron (II) nitrate, potassium iodate, potassium permanganate, ammonium chlorite, ammonium chlorate, ammonium iodate, ammonium perborate, ammonium perchlorate, ammonium periodate, tetramethylammonium chlorite, tetramethylammonium chlorate, tetramethyl ammonium iodate, tetramethylammonium perborate, tetramethylammonium perchlorate, tetramethylammonium periodate, 4-methylmorpholine N-oxide, pyridine-N-oxide and urea hydrogen peroxide, and is present in an amount of 0.005 wt % to 5 wt % in the polishing slurry composition.

11. The polishing slurry composition of claim 6, wherein the polishing slurry composition is hydrogen peroxide-free or comprises less than 1 wt % of hydrogen peroxide.

12. The polishing slurry composition of claim 6, further comprising at least one pH adjuster selected from the group consisting of:
an inorganic acid or inorganic acid salt containing at least one selected from the group consisting of hydrochloric acid, nitric acid, phosphoric acid, sulfuric acid, hydrofluoric acid, bromic acid, iodic acid and salts thereof; and
an organic acid or organic acid salt containing at least one selected from the group consisting of formic acid, malonic acid, maleic acid, oxalic acid, acetic acid, adipic acid, citric acid, propionic acid, fumaric acid, lactic acid, salicylic acid, pimelic acid, benzoic acid, succinic acid, phthalic acid, butyric acid, glutaric acid, glutamic acid, glycolic acid, asparaginic acid, tartaric acid and salts thereof.

13. The polishing slurry composition of claim 6, wherein a surface of a tungsten-containing film has a peak to valley (Rpv) of 100 nm or less and roughness (Rq) of 10 nm or less after polishing using the polishing slurry composition.

14. The polishing slurry composition of claim 6, wherein the abrasive particles have a contact area of 0.5 to 0.9, and the contact area is calculated by Equation 1:
A=C₀^{1/3}·φ^{-1/3} [Equation 1]
where A is the contact area, C₀ is concentration wt % of the abrasive particles, and φ is diameter (nm) of the particles.
